(19) United States
(12) Patent Application Publication
(10) Pub. No.: US 2026/0040967 A1
(43) Pub. Date: Feb. 5, 2026

(54) PACKAGE-PACKAGE INTERCONNECTION FOR SOLDER JOINT FAIL REDUNDANCY AND HIGH BANDWIDTH APPLICATION

(71) Applicant: Micron Technology, Inc., Boise, ID (US)

(72) Inventors: Manish Nayini, Hyderabad (IN); Sarath Edaparambil, Thrissur (IN); Nagavenkata Varaprasad Nune, Hyderabad (IN); Ramesh Nallavelli, Hyderabad (IN)

(21) Appl. No.: 19/284,607

(22) Filed: Jul. 29, 2025

Related U.S. Application Data
(60) Provisional application No. 63/678,236, filed on Aug. 1, 2024.

(51) Int. Cl. H01L 23/538; H01L 23/29; H01L 23/31; H01L 23/498; H01L 25/00; H01L 25/11

(52) U.S. Cl. CPC H01L 23/5385; H01L 23/3135; H01L 23/5386; H01L 25/112; H01L 25/50; H01L 23/295; H01L 23/49816

(57) ABSTRACT

A semiconductor device package assembly is introduced in this disclosure. The semiconductor device assembly includes a plurality of semiconductor device packages, each one of the plurality of semiconductor device packages including a package substrate having top and bottom surfaces, one or more semiconductor dice disposed on the top surface of the package substrate, and a plurality of contact pads disposed on a bottom surface of the package substrate. The semiconductor device assembly also includes a redistribution layer (RDL) on which the plurality of semiconductor device packages are disposed, and a plurality of solder balls disposed on an RDL surface opposite where the plurality of semiconductor device packages are disposed, wherein the RDL electrically connects a first semiconductor device package and a second semiconductor device package of the plurality of semiconductor device packages to one or more of the plurality of solder balls.

### CROSS-REFERENCE TO RELATED APPLICATION(S)

The present application claims priority to U.S. Provisional Patent Application No. 63/678,236, filed Aug. 1, 2024, the disclosure of which is incorporated herein by reference in its entirety.

### TECHNICAL FIELD

The present disclosure generally relates to semiconductor device assembly, and more particularly relates to semiconductor package-package interconnection for solder joint fail redundance and high bandwidth application.

### BACKGROUND

Multiple Semiconductor Chip Packaging (MCP) is a technology used in the fabrication of advanced memory products that allows for the integration of multiple semiconductor chips, such as memory chips, into a single package. This approach is beneficial for several reasons, including space-saving on the printed circuit board (PCB), improved performance due to shorter interconnect distances, and potential cost savings through integration. MCP can be implemented in various configurations. For example, Chips are placed next to each other on the same substrate and interconnected (e.g., side-by-side MCP). This method is typically used when the chips are too large to stack or when heat dissipation is a concern. By stacking chip packages side by side within a single package, MCP significantly reduces the footprint of memory components on a PCB.

One of the key methods used in MCP technology and single chip packaging technology is the use of solder balls to create electrical connections between the semiconductor packages and the PCB or lead frame. However, this process can be challenging, as various defects can arise due to mechanical stress and other factors during operation. For example, defect occurs at the interface where the solder ball connects to the semiconductor device package or the PCB. In addition, bulk solder cracks can be found within the solder ball itself. These cracks can compromise the integrity of the electrical connection and are often a result of thermal fatigue or mechanical overload. The reliability of semiconductor devices assembly is heavily dependent on the integrity of solder ball connections in MCP. The defects described above can lead to device failure, data corruption, or complete system shutdown. It is necessary to mitigate these defects during the MCP packaging process. As semiconductor technology advances and semiconductor device packages become thinner and more fragile, the development of innovative MCP techniques is desired.

### BRIEF DESCRIPTION OF THE DRAWINGS

FIG. 1 illustrates multiple semiconductor device packages bonded on a PCB substrate through solder balls.

FIG. 2 illustrates a semiconductor device package assembly according to various embodiments of the present technology.

FIGS. 3A and 3B illustrate operation of semiconductor package assembly without and with solder ball joint failing according to various embodiments of the present technology.

FIGS. 4A through 4E illustrate stages of a process for fabricating a semiconductor package assembly in accordance with various embodiments of the present technology.

FIG. 5 shows a perspective top down view of a semiconductor package assembly according to various embodiments of the present technology.

FIG. 6 shows a perspective top down view of a semiconductor package assembly configured for improving solder ball redundancy through adopting an RDL layer for the semiconductor package to package interconnection according to various embodiments of the present technology.

FIG. 7 is a top down perspective view of a semiconductor package assembly which includes multiple semiconductor packages bonded on a PCB according to various embodiments of the present technology.

FIG. 8 shows a semiconductor device package assembly and its substrate layer contact pad layout and an RDL layer pad layout according to various embodiments of the present technology.

FIG. 9 shows a method of semiconductor device package assembly according to various embodiments of the present technology.

FIG. 10 is a schematic block diagram of a system that includes a semiconductor device assembly configured in accordance with one or more embodiments of the present technology.

### DETAILED DESCRIPTION

For advanced semiconductor device assembly such as memory devices including DRAM and NAND devices, primary challenges related to the manufacturing and operation are the issue of redundancy for Ball Grid Array (BGA) solder joints and pad cracking defects. The BGA is a type of surface-mount packaging used for integrated circuits that provides a large number of interconnects with the motherboard. The BGA solder balls are crucial for the miniaturization of advanced semiconductor device assembly, allowing for a higher density of connections. However, the BGA solder joints are susceptible to a phenomenon known as Coefficient of Thermal Expansion (CTE) mismatch included fails. This mismatch occurs when different materials in the semiconductor device assembly expand and contract at different rates with temperature changes. For instance, the material forming the BGA package and the Printed Circuit Board (PCB) or lead frame to which it is soldered may have different CTE values. During the operation of the semiconductor device assembly, as the device assembly heats up and cools down, these differing expansion rates or contracting rates can induce mechanical stresses on the solder joints. Over time, these stresses can lead to solder joint or pad cracking, causing significant electrical connection problems between the chip package and the PCB or lead frame. When a BGA solder joint fails, particularly one that involves a signal pin, it can lead to partial disruption to the communication or even worse, a complete loss of communication with the affected package. This renders the DRAM or NAND module inoperative, as there is no longer a means to transmit or receive signals from the chip.

Another challenge in the design and functionality of advanced semiconductor device assembly such as DRAM and NAND devices is the need for a high bandwidth. High-performance applications demand rapid data transfer rates, which necessitates the use of Multi-Chip Packages (MCP) technology. In MCP, several dice or semiconductor packages can be assembled in a single package. This configuration allows for shorter interconnect lengths inside the substrate, which can significantly reduce signal propagation delays. Additionally, MCPs can benefit from tighter line spacing and widths within the substrate, which is not as easily achievable on standard PCBs. Ideally, for the sake of maximizing bandwidth, it would be beneficial to have all the dice within a NAND or DRAM module contained within a single package. However, this approach is not always feasible. The production of large package substrates faces two main limitations of yield and cost. As the size of the substrate increases, the likelihood of defects also increases, which can lead to lower production yields. Moreover, the manufacturing process for larger substrates is more complex and expensive. These factors make it challenging to produce large MCPs that are both cost-effective and have high yields, thus limiting the extent to which this ideal can be realized in practical applications.

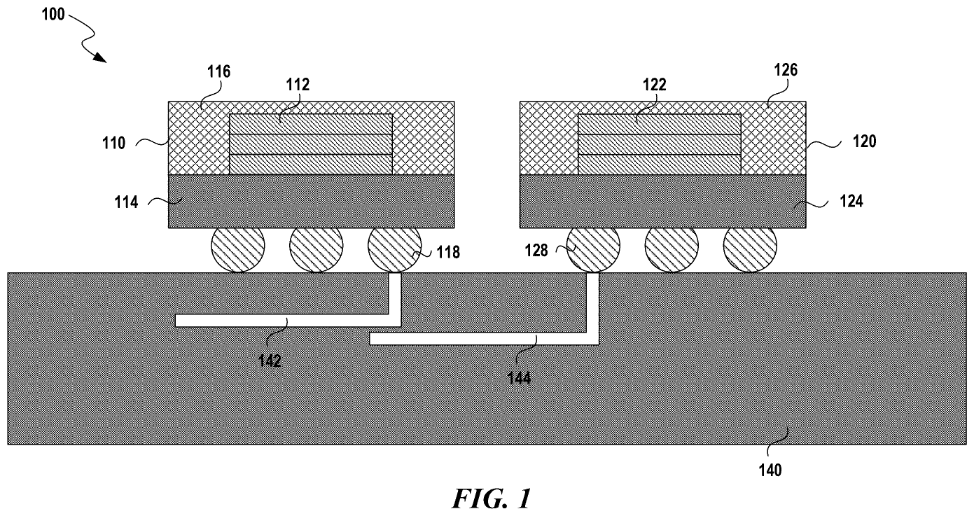

FIG. 1 illustrates multiple semiconductor device packages 110 and 120 that are bonded on a PCB 140 through solder balls 118 and 128, respectively. In this example, the semiconductor device packages 110 and 120 can be DRAM or NAND device packages. Each of the semiconductor device packages 110 and 120 includes a plurality of semiconductor dice disposed on a package substrate and encapsulated by an encapsulating material. For example, the semiconductor device package 110 includes 3 semiconductor dice 112 vertically stacked on each other and disposed above a package substrate 114. In some other examples, the package substrate 114 can be made of organic materials. The stacked semiconductor dice 112 are encapsulated by the encapsulating material 116. Solder balls 118 are disposed under the package substrate 114 and electrically interconnected with one or more PCB wirings 142. Similarly, the semiconductor device package 120 includes two or more semiconductor dice 122 vertically stacked on each other and disposed above a package substrate 124. The stacked semiconductor dice 122 are encapsulated by the encapsulating material 126. Solder balls 128 are disposed under the package substrate 124 and electrically interconnected with one or more PCB wirings 144. In this example, electrical signals transition between the semiconductor device packages 110 and 120 and the PCB 140 is conducted through the solder balls 118 and 128 and their corresponding PCB wirings. In addition, each of the semiconductor device packages 110 and 120 may include a plurality of contact pads electrically interconnecting their underneath solder balls and the stacked semiconductor dice embedded therein. The plurality of contact pads can be disposed on a bottom surface of the package substrate 114 or 124 and electrically connected to the corresponding solder balls 118 or 128. In case of solder balls joint or contact pad cracking happens during the semiconductor device routinely operation, electrical signals or power signals cannot be transferred from signal pin/power pin to the PCB, rending the semiconductor packages 110 or 120 useless. Here, the redundancy for solder ball joint or contact pad cracking fails is low.

To solve the issues and challenges described above, the present technology introduces an innovative semiconductor package assembly technology for advanced semiconductor devices such as DRAM and NAND flash memory packages. The present technology lies in the utilization of a redistribution Layer (RDL) to ingeniously interconnect individual semiconductor device packages. The RDL is not merely a passive interconnection medium but a dynamic and multifunctional layer that enhances the overall performance, reliability, and physical characteristics of the semiconductor device packages assembly. In particular, the RDL layer is composed of a plurality of conductive traces or channels, designed to establish connections between the individual DRAM and NAND packages. In the event of a Ball Grid Array (BGA) failure, which could compromise signal transmission, the RDL layer of the present technology offers an alternative signal path. It reroutes the affected signal to the BGA of an adjacent package within the combined module. This redundancy ensures continuous operation and minimizes the impact of individual package failures. In addition, the RDL layer serves as a high-speed communication bus between the individual packages. This capability is crucial for applications that demand high bandwidth and low latency, as it allows for rapid data transfer and processing across the combined memory module. In this disclosure, the RDL's design supports these high-speed data exchanges without compromising the integrity of the signals. Furthermore, by employing a fan-in approach, the RDL layer effectively reduces the BGA footprint of the combined semiconductor package assembly. This reduction in footprint is beneficial for applications where space is at a premium, although it may result in a slight decrease in BGA redundancy.

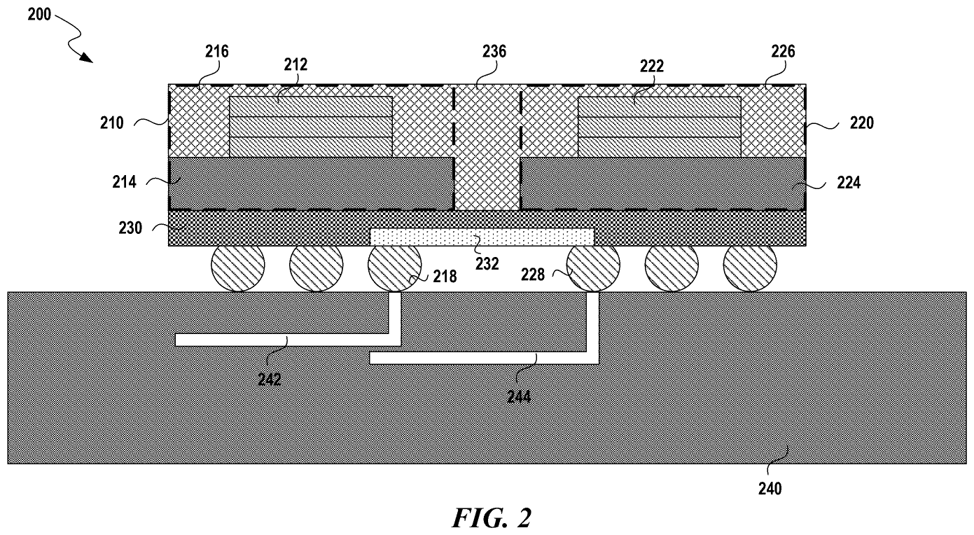

FIG. 2 illustrates a semiconductor package assembly 200 according to various embodiments of the present technology. Specifically, the semiconductor package assembly 200 includes semiconductor device packages 210 and 220 that are bonded on a PCB 240 through solder balls 218 and 228, respectively. In this example, the semiconductor device packages 210 and 220 can be DRAM or NAND device packages. Each of the semiconductor device packages 210 and 220 includes a plurality of semiconductor dice disposed on a package substrate and encapsulated by an encapsulating material. For example, the semiconductor device package 210 includes 3 semiconductor dice 212 vertically stacked on each other and disposed above a package substrate 214. The stacked semiconductor dice 212 are encapsulated by the encapsulating material 216. Similarly, the semiconductor device package 220 includes 3 semiconductor dice 222 vertically stacked on each other and disposed above a package substrate 224. The stacked semiconductor dice 222 are encapsulated by the encapsulating material 226. In this example, the semiconductor device packages 210 and 220 are disposed on an RDL 230 and covered by a molding material 236. In particular, the molding material 236 can be made of materials similar to or different from the encapsulating materials 216 and 226. Each of the molding material 236 and the encapsulating materials 216 and 226 can be made of materials comprising at least one of an epoxy-based liquid compound with granules, an epoxy-based liquid compound without granules, a granular compound, a thin-film based underfill, a thin-film based compound, a resin-based encapsulant, or a polymer. Further, the RDL 230 can be made of dielectric materials such as silicon oxide or silicon nitride having one or more layers of metal traces 232 embedded therein. Here, each of the semiconductor device packages 210 and 220 can include a plurality of contact pads disposed on the bottom surface of their substrates 214 or 224. The one or more layers of metal traces 232 can electrically connect with corresponding contact pads and solder balls. As shown in FIG. 2, the semiconductor package assembly 200 includes first BGA solder balls 218 corresponding to the semiconductor package 210 and second BGA solder balls 228 corresponding to the semiconductor package 220. The semiconductor package assembly 200 is attached the PCB 240 through bonding the solder balls 218 and 228 to corresponding PCB wirings 242 and 244.

In this example, the one or more layers of metal traces 232 of the RDL 230 electrically interconnect the semiconductor device packages 210 and 220, through bridging corresponding contact pads and solder balls of the semiconductor device packages 210 and 220. This configuration allows the semiconductor device packages 210 and 220 to behave as a nearly single package bonded on the PCB 240. In the event of a solder ball fail, the signal can be further routed through the RDL 230 (e.g., metal traces 232) to the adjoining semiconductor package within the semiconductor package assembly 200. In addition, the RDL 230 can be used for high bandwidth communication between the semiconductor device packages 210 and 220. Furthermore, by employing a fan-in approach, the RDL 230 can effectively reduce the BGA footprint of the combined semiconductor package assembly 200. This reduction in footprint is beneficial for applications where space is at a premium, and a slight decrease in BGA redundancy may be needed.

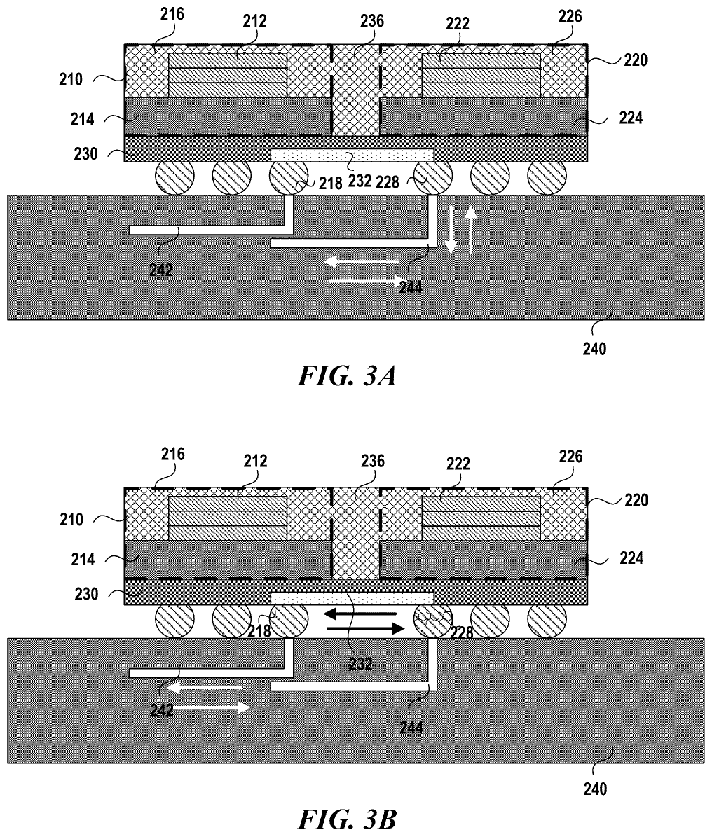

FIGS. 3A and 3B illustrate operation of the semiconductor package assembly 200 without and with a solder ball joint fail according to various embodiments of the present technology. During a normal operation shown in FIG. 3A, signal transmission between the PCB 240 and each of the semiconductor device packages 210 and 220 can be conducted through corresponding solder balls of corresponding BGA. For example, electrical signals can be transmitted from the PCB wiring 244 to the semiconductor dice 222 of the semiconductor package 220 through the second BGA, e.g., the solder ball 228 which is electrically connected to the PCB wiring 244 and corresponding contact pad of the substrate 224. Electrical signals can be transmitted between the semiconductor dice 222 and outer circuit through this interconnect channel.

When a BGA solder joint or contact pad cracking failure happens in the semiconductor package assembly 200, the present technology can provide a redundant interconnect channel for electrical signal transmission between the PCB 240 and each of the semiconductor device packages 210 or 220. As shown in FIG. 3B, when the solder ball 228 has a cracking failure, electrical signals can not be passed through the corresponding PCB wiring 244 to the semiconductor dice 222 through the solder ball 228. In this situation, the semiconductor package assembly 200 can utilize the PCB wiring 242, solder balls of the first BGA (e.g., solder ball 218), and metal traces 232 of the RDL 230 to transmit electrical signals between the PCB 240 and semiconductor package 220 contact pad connected to the solder ball 228. Here, the metal traces 232 can electrically connect the solder ball 218 of the first BGA to the contact pad of the semiconductor package 220 that is corresponding to the failed solder ball 228. To improve the redundancy for BGA solder joint or contact pad cracking failures, the metal traces 232 of the RDL 230 can be configured to form a one to one interconnection between the solder balls or contact pads of the semiconductor device packages 210 and 220. In another example, the metal traces 232 of the RDL 230 can be configured to form a one to more interconnection between the solder balls or contact pads of the semiconductor device packages 210 and 220, e.g., interconnecting one solder ball of the first BGA of the semiconductor package 210 to multiple contact pads of the semiconductor package 220. In some other examples, the metal traces 232 of the RDL 230 can be configured to form a “more to one” interconnection between the solder balls or contact pads of the semiconductor device packages 210 and 220, e.g., interconnecting multiple solder balls of the first BGA of the semiconductor package 210 to an individual contact pad of the semiconductor package 220.

In comparison to the semiconductor package assembly illustrated in FIGS. 2, 3A and 3B, conventional semiconductor package assembly of FIG. 1 has a limited redundancy for BGA solder joint or contact pad cracking failures. Specifically, the solder balls 118 and 128 are respectively interconnected to corresponding PCB wiring 142 and 144, and corresponding contact pads. When a BGA solder joint or contact pad cracking failure happens, the interconnect channel between PCB 140 and corresponding contact pad of the semiconductor device packages 110 or 120 breaks and electrical signal can no longer pass there through.

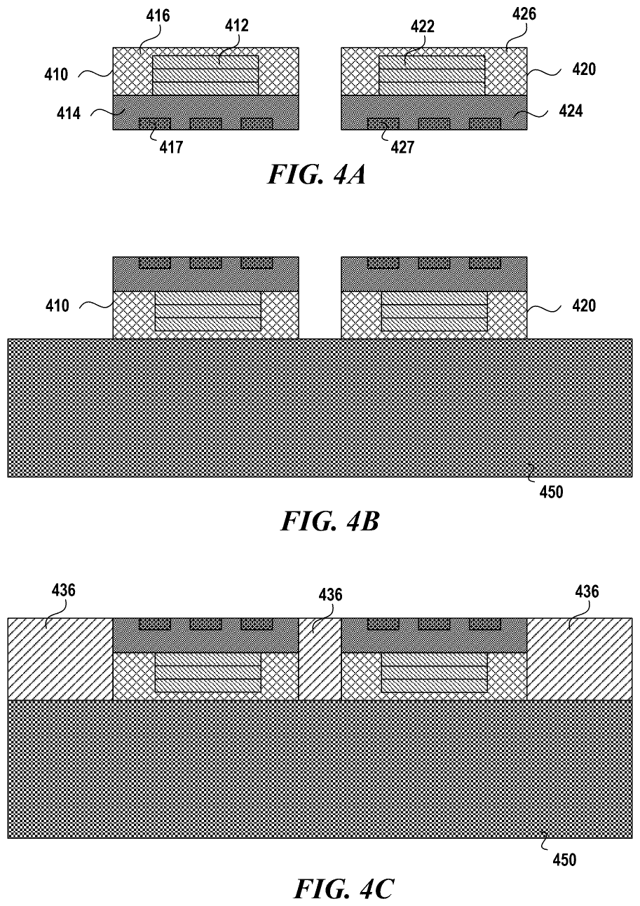

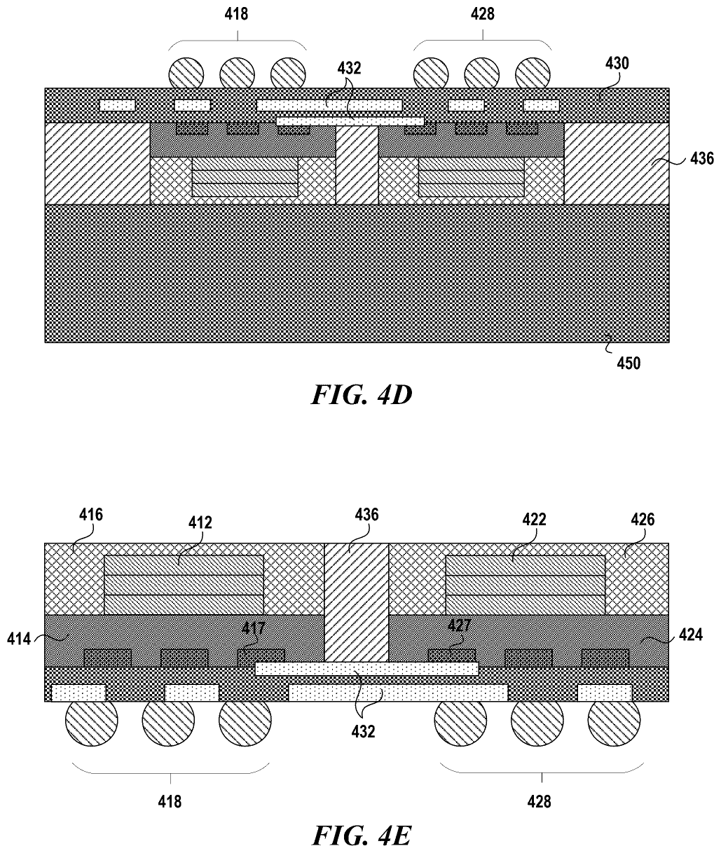

FIGS. 4A through 4E illustrate stages of a process 400 for fabricating the semiconductor package assembly in accordance with various embodiments of the present technology. For example, individual semiconductor packages can be formed by singulating a semiconductor device wafer. As shown in FIG. 4A, semiconductor packages 410 and 420 can be diced using a blade dicing, a plasma dicing, or a laser dicing process. Each of the semiconductor packages 410 and 420 includes a plurality of semiconductor dice 412 or 422 that are vertically stacked. The semiconductor dice 412 are disposed on a package substrate 414 and encapsulated by the encapsulating material 416. The package substrate 414 includes a plurality of contact pads 417 disposed on its bottom surface. Similarly, semiconductor dice 422 are disposed on a package substrate 424 and encapsulated by the encapsulating material 426. The package substrate 424 includes a plurality of contact pads 427 disposed on its bottom surface.

In a next step, the individual semiconductor packages can be bonded on a carrier wafer. As shown in FIG. 4B, the semiconductor packages 410 and 420 can be attached on a glass carrier 450, by having the backside surface of the semiconductor packages 410 and 420 attached to the glass carrier 450. Here, the contact pads 417 and 427 are away from the glass carrier 450 and exposed. An adhesive layer can be adopted in this step to bond the semiconductor packages 410 and 420 on the glass carrier 450. In some other examples, multiple semiconductor packages, e.g., up to 50 memory device packages, can be bonded on the glass carrier 450 for downstream semiconductor package assembly processes.

Once the semiconductor packages are bonded on the carrier wafer, a mold material can be applied to surround and cover the semiconductor packages. As shown in FIG. 4C, the molding material 436 can be applied to cover the semiconductor packages 410 and 420. In particular, the molding material 436 is filled into the gap between the semiconductor packages 410 and 420 for electrical isolation. In this example, the molding material 436 can be made of a material similar to or different to the encapsulating materials 416 and 426. Here, it is preferred to select materials having similar coefficient of thermal expansion (CTE) and elastic modulus for the molding material 436 and encapsulating materials 416 and 426 to improve the reliability of the final semiconductor package assembly. In this example, a chemical mechanical polishing (CMP) process can be conducted to planarize the frontside surface of the semiconductor packages 410 and 420 and expose their contact pads 417 and 427.

FIG. 4D shows a step of fabricating an RDL 430 and BGAs 418 and 428 above the RDL 430. In this example, RDL 430 including the one or more metal traces 432 embedded therein can be formed using semiconductor lithography process, patterning process, thin film deposition process, and etching process. In particular, as shown in FIG. 4D, the RDL 430 can be formed above the contact pads of the semiconductor device packages 410 and 420. Specifically, a dielectric layer can be deposited above the semiconductor device packages 410 and 420. In some embodiments, the dielectric layer can include silicon oxide or silicon nitride. The RDL 430 and metal traces 432 can be formed by patterning the dielectric layer with openings/indentations and filling them with conductive materials such as aluminum, tungsten, cobalt, nickel, or any other suitable conductive materials. Notably, the RDL 430 can be connected to one or more contact pads and solder balls the BGAs 418 and 428 for electrical interconnection. Above the RDL 430, solder balls can be further formed thereon to form the first BGA 418 and the second BGA 428. In some examples, the first BGA 418 and the second BGA 428 respectively correspond to contact pads of the semiconductor packages 410 and 420. Here, BGA solder balls can be attached to the RDL 430 and then reflowed.

In a next step shown in FIG. 4E, the semiconductor device packages 410 and 420 can be singulated and debonded from the glass carrier 450. Here, the semiconductor device packages 410 and 420 can be diced to form a semiconductor package assembly, which can be debonded from the glass carrier 450 using a particular debonding technology such as mechanical debonding process, thermal slide debonding process, laser debonding process, or a room temperature debonding process.

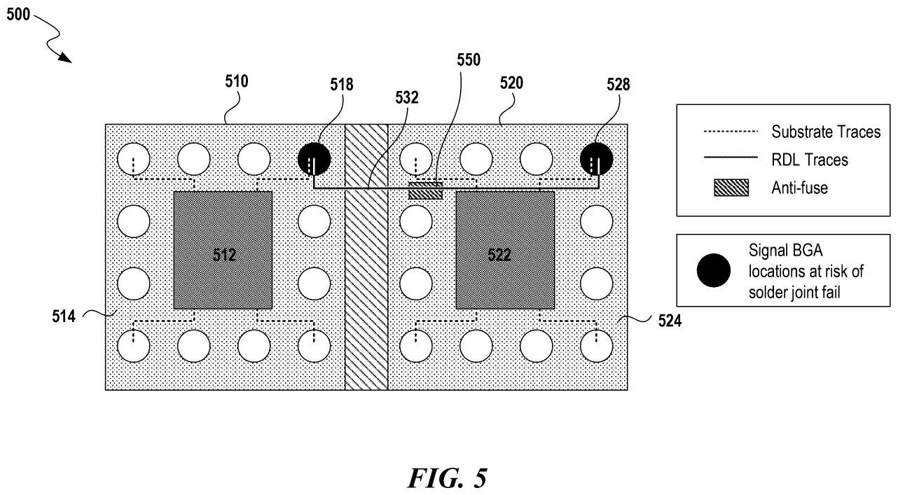

The solder ball redundancy can be improved through adopting an RDL layer for the semiconductor package to package interconnection, as disclosed in FIG. 2 through FIG. 4E of this disclosure. For example, FIG. 5 shows a perspective top down view of a semiconductor package assembly 500 according to various embodiments of the present technology. In this example, semiconductor dice 512 and 22 are respectively interconnected to corresponding BGA solder balls through substrate traces drawn in dashed lines. Here, BGA solder balls 518 and 528 at risk of solder joint fail are labeled as black circle and interconnected by an RDL metal trace 532 in solid line. Particularly, this RDL metal trace 532 passes through an anti-fuse device 550 which is configured to control the electrical interconnection between the risky BGA solder balls 518 and 528. In some other examples, similar configuration of RDL metal trace 532 and anti-fuse device 550 can be made for all BGA solder balls tend to have a reliability issue.

In this example, the anti-fuse device 550 can be a non-volatile memory semiconductor device that becomes conductive when a programmed voltage is applied thereon. Additionally, the anti-fuse device 550 can be embedded in the RDL of the semiconductor package assembly 500 or in the package substrates 514 and 524 of the semiconductor device packages 510 and 520. Depending on the routing strategy and semiconductor device assembly/manufacturing process, the fabrication and position of the anti-fuse device 550 can vary.

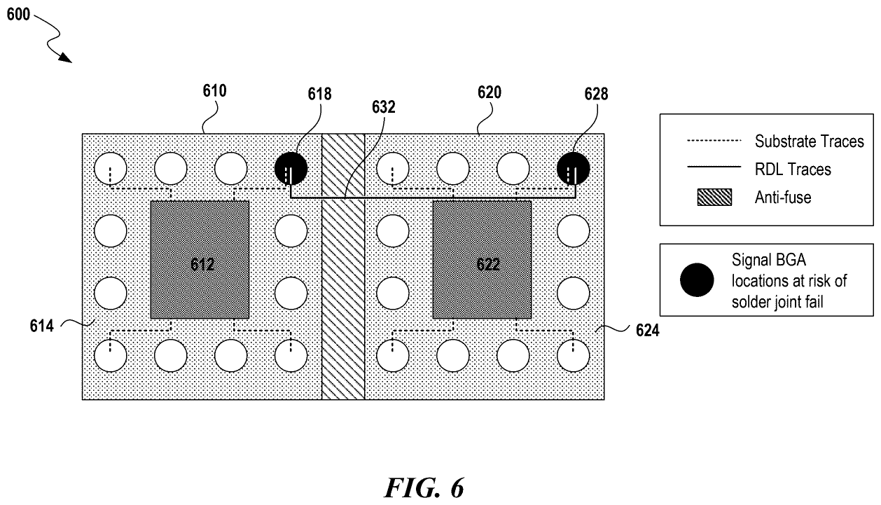

In another example, FIG. 6 shows a perspective top down view of a semiconductor package assembly 600 configured for improving solder ball redundancy through adopting an RDL layer for the semiconductor package to package interconnection. In this example, semiconductor dice 612 and 611 are respectively interconnected to corresponding BGA solder balls through substrate traces drawn in dashed lines. Here, BGA solder balls 618 and 628 at risk of solder joint fail are labeled as black circle and interconnected by an RDL metal trace 632 in solid line. Particularly, this RDL metal trace 632 directly interconnects the risky BGA solder balls 518 and 528, without passing through an anti-fuse device. In this example, additional RDL metal traces can be fabricated to permanently interconnect corresponding BGA solder balls that tend to have a reliability issue and that are disposed on the semiconductor device package 610 and 620 respectively.

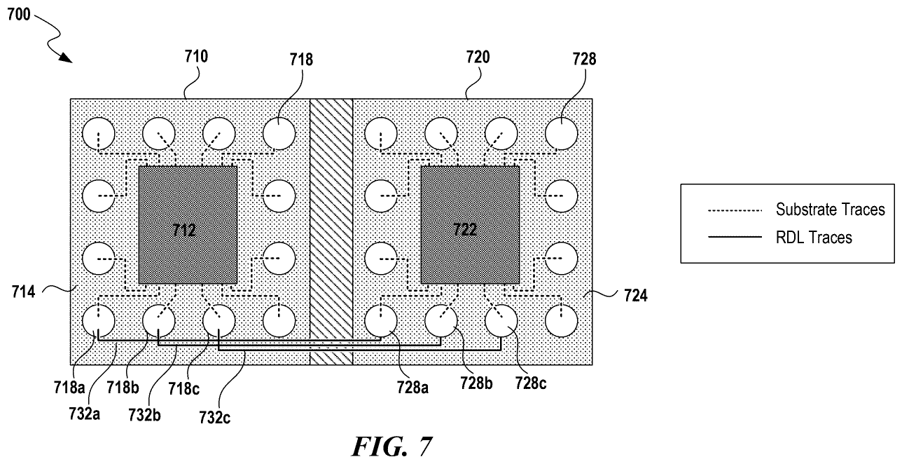

FIG. 7 shows a top down perspective view of a semiconductor package assembly 700 which includes semiconductor packages 710 and 720 bonded on a PCB. Each one of the semiconductor packages 710 and 720 includes a package substrate 714 or 724 and a semiconductor dice 712 or 722 mounted on thereon. The packages 710 and 720 are electrically interconnected to the PCB by solder joints 718 and 728, through the substrate traces in dashed lines. In this example, some of the solder joints 718 and 728 are coupled to each other through RDL metal traces, e.g., 732a, 732b, and 732c. These RDL metal traces provide additional electrical interconnections between the semiconductor dice 712 and 722, as well as inter-package connections between the solder balls 718a and 728a, 718b and 728b, and 718c and 728c. In this example, the RDL traces such as 732a, 732b, and 732c have a narrower line/width spacing than the substrate traces and PCB traces shown in dashed lines, which allow for a greater number of signals to be routed in the semiconductor package assembly 700. In this example, instead of passing through PCB traces, the signals can pass through dense RDL layer traces. In particular, the RDL metal traces 732a, 732b, and 732c also reduce the overall channel length between the packages 710 and 720, which improves the bandwidth of operation. Moreover, the RDL metal traces 732a, 732b, and 732c avoid the issues involving BGA fanout, such as layout complexity and impedance mismatch, that may arise from using only the substrate and PCB traces.

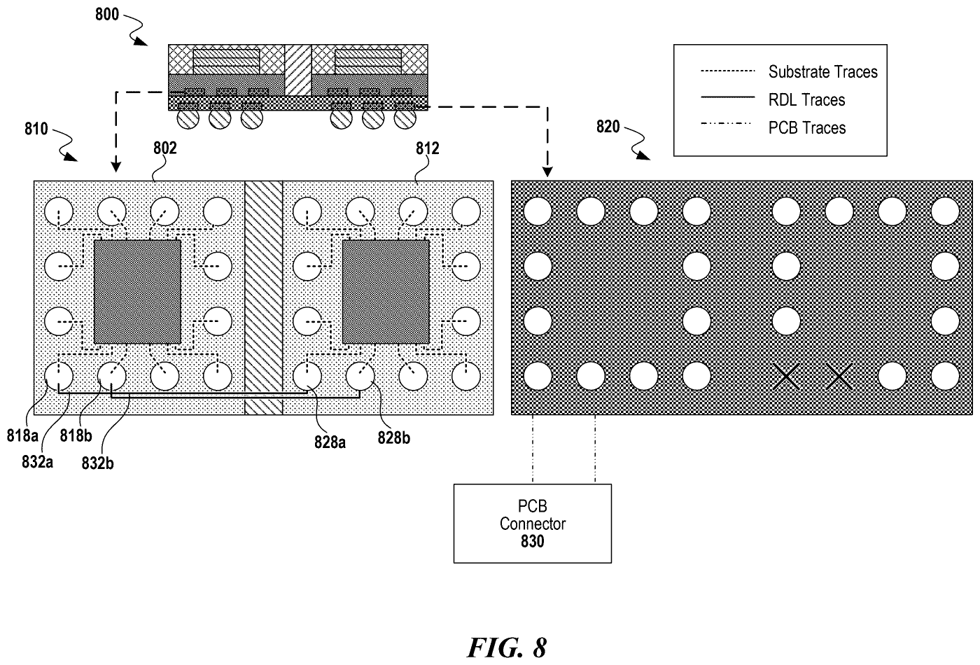

As described earlier in this disclosure, the present technology can further reduce the BGA footprint in the semiconductor device package assembly. For example, FIG. 8 shows a semiconductor device package assembly 800 and its substrate layer contact pad layout 810 and RDL layer pad layout 820. In this example, the semiconductor device package assembly 800 can have a similar structure to the semiconductor device package assembly described in FIG. 2 or FIG. 4E, e.g., having multiple singulated semiconductor device packages disposed above an RDL layer. As shown in the substrate layer contact pad layout 810, multiple RDL metal traces in solid lines can interconnect contact pads 818a and 818b of the semiconductor package 802 and the contact pads 828a and 828b of the semiconductor package 812, respectively. In this example, the BGA pins corresponding to the contact pads 818a and 818b can be shared by the semiconductor packages 802 and 812, e.g., through the RDL metal traces 832a and 832b. As a result and for the purpose of reducing the footprint of BGA of the semiconductor device package assembly, solder balls corresponding to the contact pads 828a and 828b can be removed, as shown on the RDL layer pad layout 820. As shown in FIG. 8, a PCB connector 830 can be utilized to configure the RDL metal traces in interconnecting corresponding contact pads of the semiconductor device packages 802 and 812. In some other examples, a host controller or a standalone controller can be adopted to configure the RDL traces. Here, an original BGA footprint including 24 solder balls can be optimized to a reduced footprint of 22 solder balls, through implementing the RDL metal traces 832a and 832b. In some other examples, a plurality of RDL metal traces can be fabricated in the semiconductor device package assembly 800 to further reduce the BGA footprint for scaling.

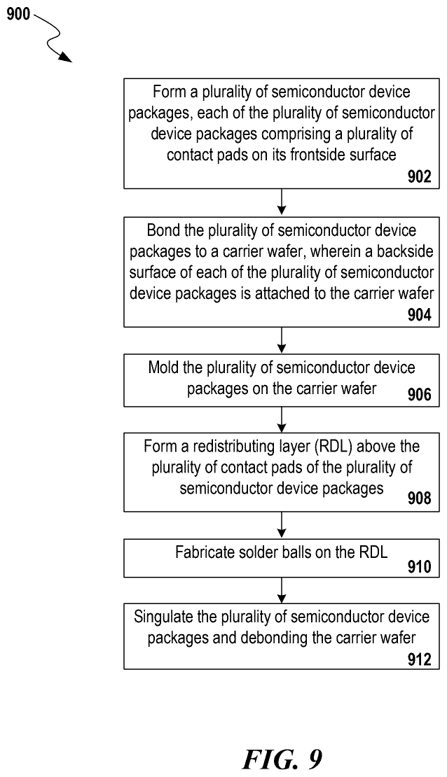

FIG. 9 shows a method 900 of semiconductor device package assembly in accordance with various embodiments of the present technology. For example, the method 900 includes forming a plurality of semiconductor device packages, each of the plurality of semiconductor device packages comprising a plurality of contact pads on its frontside surface, at 402. For example, semiconductor device packages 410 and 420 can be formed by dicing a semiconductor device wafer. Each of the semiconductor device packages 410 and 420 includes a plurality of contact pads 417 and 427 disposed on their frontside surfaces, as shown in FIG. 4A.

The method 900 also includes bonding the plurality of semiconductor device packages to a carrier wafer, wherein a backside surface of each of the plurality of semiconductor device packages is attached to the carrier wafer, at 404. For example, the semiconductor device packages 410 and 420 can be bonded on the glass carrier 450. As shown in FIG. 4B, the backside surfaces of the semiconductor device packages 410 and 420 can be attached to a frontside surface of the glass carrier 450.

In addition, the method 900 includes molding the plurality of semiconductor device packages on the carrier wafer, at 906. For example, molding material 436 can be applied to cover the semiconductor device packages 410 and 420 and the frontside surface of the glass carrier 450. Specifically, the molding material 436 isolates the semiconductor device packages 410 and 420 horizontally above the glass carrier 450, as shown in FIG. 4C.

The method 900 also includes forming an RDL above the plurality of contact pads of the plurality of semiconductor device packages, at 908. For example, the RDL 430 including metal traces 432 can be formed above the frontside surfaces of the semiconductor device packages 410 and 420 through lithography patterning processes, etching processes, and thin film deposition processes. As shown in FIG. 4D, the RDL layer can be disposed above the plurality of contact pads (e.g., 417 and 427) of the semiconductor device packages 410 and 420. Specifically, the metal traces 432 can electrically interconnects one or more contact pads of the semiconductor device package 410 with corresponding one or more contact pads of the semiconductor device packages 420.

Further, the method 900 includes fabricating solder balls on the RDL, at 910. For example, solder balls can be formed through solder paste deposition and reflow soldering processes. As shown in FIG. 4D, solders balls can be formed in the first BGA 418 and the second BGA 428.

Lastly, the method 900 includes singulating the plurality of semiconductor device packages and debonding the carrier wafer, at 912. For example, semiconductor dicing process such as blade dicing process, plasma dicing process, or laser dicing process can be adopted to cut, towards molding material 436 and RDL 430, the semiconductor device packages 410 and 420, as shown in FIG. 4E.

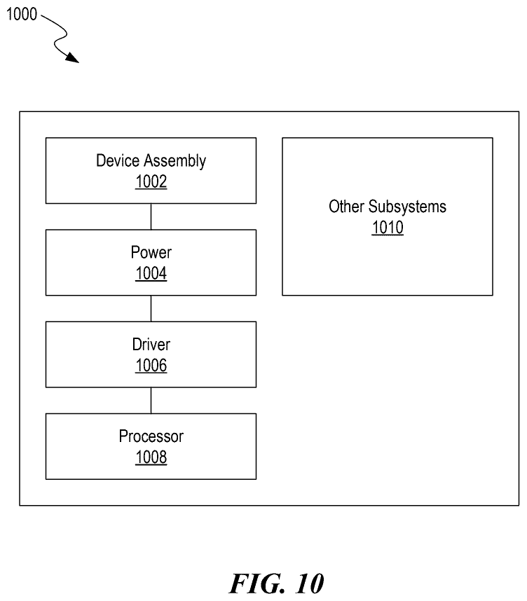

Any one of the semiconductor die assembly technology described above with reference to FIGS. 2 to 9 can be incorporated into any of a myriad of larger and/or more complex systems, a representative example of which is system 1000 shown schematically in FIG. 10. The system 1000 can include a semiconductor device packages assembly (e.g., or a discrete semiconductor device) 1002, a power source 1004, a driver 1006, a processor 1008, and/or other subsystems or components 1010. The semiconductor device packages assembly 1002 can include features generally similar to those of the semiconductor device assembly described above with reference to FIGS. 2 to 9. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a plurality of semiconductor device packages, each one of the plurality of semiconductor device packages comprising:
a package substrate having top and bottom surfaces,
one or more semiconductor dice disposed on the top surface of the package substrate, and
a plurality of contact pads disposed on a bottom surface of the package substrate;
a redistribution layer (RDL) on which the plurality of semiconductor device packages are disposed; and
a plurality of solder balls disposed on an RDL surface opposite where the plurality of semiconductor device packages are disposed,
wherein the RDL electrically connects a first semiconductor device package and a second semiconductor device package of the plurality of semiconductor device packages to one or more of the plurality of solder balls.

2. The semiconductor device assembly of claim 1, wherein the semiconductor dice are vertically stacked and electrically interconnected.

3. The semiconductor device assembly of claim 1, wherein the RDL comprises one or more metal traces.

4. The semiconductor device assembly of claim 3, wherein the one or more metal traces electrically connect one or more contact pads of the first semiconductor device package and corresponding one or more contacts pads of the second semiconductor device package.

5. The semiconductor device assembly of claim 4, wherein the solder balls are disposed under a bottom surface of the RDL.

6. The semiconductor device assembly of claim 5, wherein the plurality of solder balls comprise a first ball grid array (BGA) corresponding to and electrically connects to the first semiconductor device package and a second BGA corresponding to and electrically connects to the second semiconductor device package.

7. The semiconductor device assembly of claim 6, wherein the one or more metal traces electrically connect one or more solder balls of the first BGA and corresponding one or more solder balls of the second BGA.

8. The semiconductor device assembly of claim 6, wherein solder balls of the first BGA are electrically connected to the one or more contact pads of the first semiconductor device package, and wherein solder balls of the second BGA are electrically connected to the one or more contact pads of the second semiconductor device package.

9. The semiconductor device assembly of claim 6, wherein the first BGA has a larger number of solder balls than the second BGA and wherein the second BGA has a smaller footprint than the first BGA.

10. The semiconductor device assembly of claim 3, wherein the one or more metal traces are disposed in multiple layers within the RDL, and wherein the RDL further comprises a dielectric layer separating multiple metal traces of the one or more metal traces.

11. The semiconductor device assembly of claim 10, wherein the RDL further comprises a passivation layer disposed on a bottom surface of the RDL.

12. The semiconductor device assembly of claim 1, wherein each one of the first semiconductor device package and the second semiconductor device package comprises an encapsulating material, the encapsulating material surrounding and covering corresponding one or more semiconductor dice.

13. The semiconductor device assembly of claim 12, further comprise a molding material that surrounds and covers the first semiconductor device package and the second semiconductor device package, wherein the molding material separates the first semiconductor device package and the second semiconductor device package above the RDL.

14. The semiconductor device assembly of claim 13, wherein the molding material and the encapsulating material are made of materials comprising at least one of an epoxy-based liquid compound with granules, an epoxy-based liquid compound without granules, a granular compound, a thin-film based underfill, a thin-film based compound, a resin-based encapsulant, or a polymer.

15. The semiconductor device assembly of claim 13, wherein the molding material and the encapsulating material have a different material composition.

16. The semiconductor device assembly of claim 3, further comprises one or more anti-fuses, wherein at least one of the one or more metal traces passes through a corresponding anti-fuse of the one or more anti-fuses.

17. A semiconductor device assembly, comprising:
a first semiconductor device package and a second semiconductor device package, each compromising one or more semiconductor dice and a package substrate disposed below corresponding one or more semiconductor dice;
a redistribution layer (RDL) on which the first and the second semiconductor device packages are disposed, the RDL comprises one or more metal traces; and
a first ball grid array (BGA) comprising a first plurality of solder balls corresponding to the first semiconductor device package and a second BGA comprising a second plurality of solder balls corresponding to the second semiconductor device package, wherein the first BGA and the second BGA are disposed under the RDL,
wherein the one or more metal traces electrically connect one or more solder balls of the first BGA to one or more solder balls of the second BGA.

18. The semiconductor device assembly of claim 17, further comprises an anti-fuse, wherein one of the one or more metal traces passes through the anti-fuse.

19. The semiconductor device assembly of claim 17, wherein the first BGA has a larger number of solder balls than the second BGA and wherein the second BGA has a smaller footprint than the first BGA.

20. A method of semiconductor device assembly, comprising:
forming a plurality of semiconductor device packages, each of the plurality of semiconductor device packages comprising a plurality of contact pads on its frontside surface;
bonding the plurality of semiconductor device packages to a carrier wafer, wherein a backside surface of each of the plurality of semiconductor device packages is attached to the carrier wafer;
molding the plurality of semiconductor device packages on the carrier wafer;
forming a redistributing layer (RDL) above the plurality of contact pads of the plurality of semiconductor device packages;
fabricating solder balls on the RDL; and
singulating the plurality of semiconductor device packages and debonding the carrier wafer.
